(19) United States
(12) Patent Application Publication
(10) Pub. No.: US 2010/0270658 A1
(43) Pub. Date: Oct. 28, 2010

(54) SEMICONDUCTOR DEVICE AND METHOD FOR PRODUCING SAME

(76) Inventors: Kazuo Nakagawa, Osaka (JP); Michiko Takei, Osaka (JP); Yasumori Fukushima, Osaka (JP); Kazuhide Tomiyasu, Osaka (JP); Shin Matsumoto, Osaka (JP); Kenshi Tada, Osaka (JP); Yutaka Takafuji, Osaka (JP)

Correspondence Address: BIRCH STEWART KOLASCH & BIRCH, PO BOX 747, FALLS CHURCH, VA, 22040-0747, US

(21) Appl. No.: 12/746,156

(22) PCT Filed: Sep. 12, 2008
(86) PCT No.: PCT/JP2008/066574

§ 371 Date: Jun. 3, 2010

(30) Foreign Application Priority Data
Dec. 27, 2007 (JP) 2007-338330

(51) Int. Cl. H01L 29/02; H01L 21/762

(52) U.S. Cl. 257/640; 438/458; 257/E29.002; 257/E21.568

(57) ABSTRACT

A method is disclosed for producing a semiconductor device produced by (i) doping hydrogen ions or rare gas ions into a device substrate in which a transfer layer (16) is formed, (ii) then bonding the device substrate to a carrier target substrate, and (iii) transferring the transfer layer (16) onto the carrier substrate (30) by cleaving the device substrate along a portion in which the hydrogen ions or the rare gas ions are doped, the method including providing a blocking layer (11) for blocking diffusion of a bubble-causing substance between (i) a bonding surface (13), which serves as a bonding interface between the device substrate and the carrier substrate, and (ii) the transfer layer (16). This prevents bubbles from forming at the bonding interface between the semiconductor substrate and the target substrate due to the diffusion of the bubble-causing substance.

### TECHNICAL FIELD

The present invention relates to a semiconductor device and a method for producing the semiconductor device. More particularly, the present invention relates to (i) a semiconductor device produced by transferring a transfer layer, formed on a semiconductor substrate, onto a target substrate such as a glass substrate, and to (ii) a method for producing the semiconductor device.

### BACKGROUND ART

In recent years, studies have been conducted on techniques for forming, on a target substrate such as a glass substrate, a device such as a TFT (thin film transistor) including a monocrystalline semiconductor film.

Among such techniques is a so-called transfer technique, by which a transfer layer is transferred onto a target substrate, such as a glass substrate, which is commonly called a production substrate. The transfer layer includes, for example, (i) a monocrystalline semiconductor film formed on a semiconductor substrate such as a SOI (Silicon on Insulator) wafer and a monocrystalline silicon wafer, or (ii) a device including such a monocrystalline semiconductor film.

According to the transfer technique, the transfer layer is transferred by (i) doping a predetermined concentration of hydrogen ions or rare gas ions into the semiconductor substrate, typically (ii) heat-treating the semiconductor substrate so as to form microbubbles in a doping section of the semiconductor substrate, and (iii) cleaving the semiconductor substrate so as to peel the transfer layer from the rest of the semiconductor substrate along a plane formed by the microbubbles (see, for example, Patent Literatures 1 through 4).

The transfer technique makes it possible to, for example, form a polycrystalline semiconductor film and a monocrystalline semiconductor film in their respective regions of a target substrate such as a glass substrate. Hence, it is possible to (i) form, in the region where the monocrystalline semiconductor film is formed, a device, such as a timing controller and a microprocessor, which requires higher performance, and to (ii) form other devices in the region where the polycrystalline semiconductor film is formed.

Further, in a case where, for example, a device such as a transistor (i.e., a monocrystalline silicon transistor) including a monocrystalline silicon thin film is formed on a monocrystalline silicon wafer, microfabrication of monocrystalline silicon can be performed easily.

### Citation List

Patent Literature 1

Japanese Patent Application Publication, Tokukai, No. 2004-119636 A (Publication Date: Apr. 15, 2004) (Corresponding U.S. Patent Application No. 2003/183876 (Publication Date: Oct. 2, 2003); Corresponding U.S. Patent Application No. 2007/063281 (Publication Date: Mar. 22, 2007))

Patent Literature 2

Japanese Patent Application Publication, Tokukai, No. 2004-134675 A (Publication Date: Apr. 30, 2004) (Corresponding U.S. Patent Application No. 2004/061176 (Publication Date: Apr. 1, 2004))

Patent Literature 3

Japanese Patent Application Publication, Tokukai, No. 2004-288780 A (Publication Date: Oct. 14, 2004) (Corresponding U.S. Patent Application No. 2004/183133 (Publication Date: Sep. 23, 2004); Corresponding U.S. Patent Application No. 2007/235734 (Publication Date: Oct. 11, 2007))

Patent Literature 4

Japanese Patent Application Publication, Tokukai, No. 2006-100831 A (Publication Date: Apr. 13, 2006) (Corresponding U.S. Patent Application No. 2006/068565 (Publication Date: Mar. 30, 2006); Corresponding U.S. Patent Application No. 2006/073678 (Publication Date: Apr. 6, 2006); Corresponding U.S. Patent Application No. 2007/066035 (Publication Date: Mar. 22, 2007); Corresponding U.S. Patent Application No. 2007/122998 (Publication Date: May 31, 2007))

### SUMMARY OF INVENTION

The above method, however, poses the following problem: For example, when the transfer layer is transferred, or when the heat treatment is performed after the transfer, a bubble-causing substance from the transfer layer side is diffused along an interface on which the semiconductor substrate and a target substrate are bonded to each other. This causes bubbles to form at the bonding interface, and thus impairs device properties.

The present invention has been accomplished in view of the above problem. It is an object of the present invention to prevent bubbles from forming at a bonding interface between a semiconductor substrate and a target substrate due to diffusion of a substance that causes bubbles.

A semiconductor device for solving the above problem is a semiconductor device produced by (i) doping hydrogen ions or ions of a rare gas into a semiconductor substrate in which a transfer layer is formed, then (ii) bonding the semiconductor substrate to a target substrate, and (iii) transferring the transfer layer onto the target substrate by cleaving the semiconductor substrate at a portion in which the hydrogen ions or the rare gas ions are doped, the semiconductor device including: a blocking layer for blocking substance diffusion, the blocking layer being provided between (i) a bonding interface between the semiconductor substrate and the target substrate and (ii) the transfer layer.

A method for solving the above problem is a method for producing a semiconductor device produced by (i) doping hydrogen ions or ions of a rare gas into a semiconductor substrate in which a transfer layer is formed, then (ii) bonding the semiconductor substrate to a target substrate, and (iii) transferring the transfer layer onto the target substrate by cleaving the semiconductor substrate at a portion in which the hydrogen ions or the rare gas ions are doped, the method including: providing a blocking layer for blocking substance diffusion between (i) a bonding interface between the semiconductor substrate and the target substrate and (ii) the transfer layer.

The blocking layer may preferably block diffusion of a substance from the transfer layer which substance causes a bubble. The blocking layer may preferably be made of a material having an intracrystalline pore or intercrystalline gap smaller than the substance which causes the bubble.

The substance which causes the bubble is exemplified by ions or molecules of at least one selected from the group consisting of water, hydrogen, and a hydrocarbon. In other words, the blocking layer may, for example, be a blocking layer for blocking diffusion of ions or molecules of at least one selected from the group consisting of water, hydrogen, and a hydrocarbon.

As described above, the blocking layer is provided between the bonding interface and the transfer layer. As a result, the bubble-causing substance from the transfer layer can be prevented from being diffused to the bonding interface between the semiconductor substrate and the target substrate due to, e.g., a heat treatment performed for the transfer. Hence, each of the above arrangements prevents bubbles from forming at the bonding interface.

### BRIEF DESCRIPTION OF DRAWINGS

FIG. 1 is a flowchart partially showing a process of producing a semiconductor device in accordance with an embodiment of the present invention.

FIG. 2 is a cross-sectional view schematically illustrating an example of a structure of a main portion of the semiconductor substrate which is bonded to a target substrate.

FIG. 3 is a cross-sectional view schematically illustrating a structure of the main portion of the semiconductor substrate observed in a state where a semiconductor substrate has been bonded to the target substrate and a peel layer has been peeled.

FIG. 4 is a cross-sectional view schematically illustrating an arrangement of the main portion of the semiconductor substrate observed in a state where, after the peel layer has been peeled, a thickness of an active layer has been reduced and a protection insulating film has been formed.

FIG. 5 is a cross-sectional view schematically illustrating an arrangement of the main portion of the semiconductor substrate observed in a state where second wiring layers have been formed.

FIG. 6

(a) to (c) are cross-sectional view illustrating steps through which the semiconductor substrate is attached to the target substrate, and the transfer layer is transferred from the semiconductor substrate onto the target substrate.

FIG. 7 is a cross-sectional view illustrating another example of the semiconductor substrate which is bonded to the target substrate.

FIG. 8 is a cross-sectional view schematically illustrating a structure of the semiconductor device produced in accordance with the embodiment of the present invention.

### REFERENCE SIGNS LIST

1 wafer substrate
2 oxide film
3 active layer
4 LOCOS film
5 gate insulating film
6 gate electrode
7 interlayer insulating film
8 contact hole
9 first wiring layer
10 planarizing layer
11 blocking layer
12 bonding layer
13 bonding surface
14 peel surface
15 peel layer
16 transfer layer
20 device substrate (semiconductor substrate)
30 carrier substrate (target substrate)
31 light-transmitting substrate
41 protection insulating film
42 contact hole
43 second wiring layer
120 polycrystalline silicon thin film transistor
121 interlayer insulating film
130 monocrystalline silicon thin film transistor
140 metal wire

### DESCRIPTION OF EMBODIMENTS

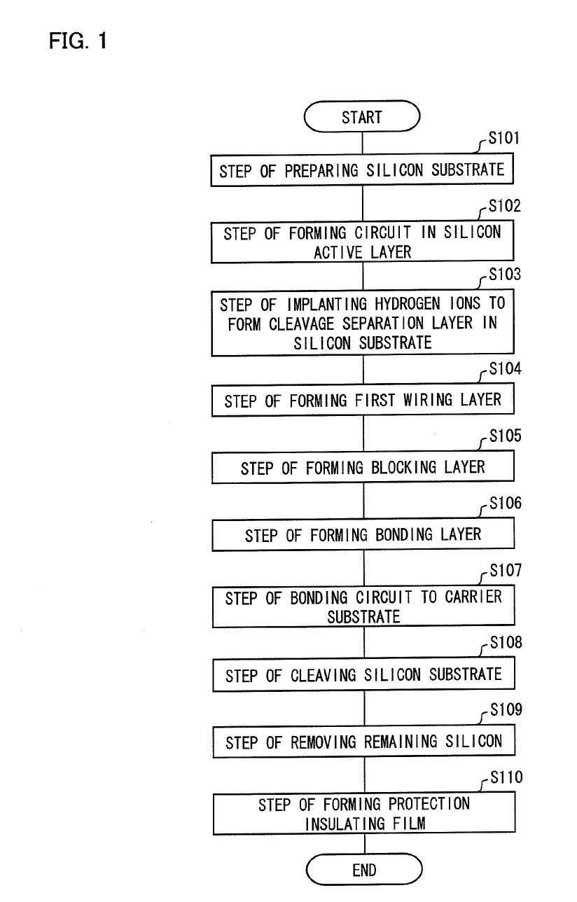

One embodiment of the present invention is described below with reference to FIGS. 1 through 8.

A method of the present embodiment for producing a semiconductor device is a method for producing a semiconductor device by the so-called transfer technique, by which a transfer layer formed on a semiconductor substrate is transferred onto a target substrate commonly called a production substrate.

The above transfer layer formed on the semiconductor substrate refers to (i) a semiconductor film formed on a semiconductor substrate, or (ii) a device including such a semiconductor film; typically, (i) a monocrystalline film, such as a monocrystalline silicon film, formed on a SOI wafer or a monocrystalline silicon wafer, or (ii) a device including such a monocrystalline film.

The following describes a silicon-based circuit as an example of the transfer layer. The description deals with an example case in which the silicon-based circuit is transferred by the transfer technique onto a target substrate (hereinafter referred to as “carrier substrate”) which is commonly called a production substrate and on which a device is to be finally formed.

FIG. 1 is a flowchart showing in a simplified manner an example flow of steps through which the silicon-based circuit is transferred onto the carrier substrate by the transfer technique. Note that the flowchart described below merely shows an example flow of the steps. Hence, some of the steps below may be omitted, or may alternatively be performed simultaneously or in reverse order.

First, as indicated in step (hereinafter referred to as “S”) 101, a silicon substrate (wafer substrate) is prepared which includes a silicon active layer as an active layer.

Then, a circuit is formed in the silicon active layer (S102). Examples of the circuit encompass: a TFT (thin film transistor); a CMOS (complementary metal oxide semiconductor) circuit; and a VLSI (very large scale integrated circuit).

Next, hydrogen ions (H⁺), for example, are doped into the silicon substrate so that a hydrogen ion-doped layer is formed as a cleavage separation layer (region in which a cleavage is to be caused) for cleaving and peeling the silicon substrate (S103). Alternatively, rare gas ions may be doped into the silicon substrate to form the cleavage separation layer.

After the above step, first wiring layers are formed on the circuit so as to be connected to the circuit (S104). Then, on the first wiring layers, a blocking layer is formed which blocks substance diffusion (S105).

Then, on the blocking layer, a bonding layer is formed which serves to bond the silicon substrate (device substrate), in which the circuit is formed, to the carrier substrate (S106). The bonding layer is planarized by, e.g., CMP (chemical mechanical polishing).

Next, the device substrate is bonded to the carrier substrate (S107). A peel layer is then peeled (cleaved) from the rest of the device substrate along the cleavage separation layer formed in the device substrate (S108).

After the above step, unnecessary silicon remaining after the cleaving is removed (S109). A protection insulating film is then formed (S110).

With reference to FIGS. 1 through 8, the following describes in detail (i) the method of the present embodiment for producing a semiconductor device, and (ii) an arrangement of the semiconductor device produced in accordance with the present embodiment.

<Arrangement of Semiconductor Device>

The semiconductor device of the present embodiment is a semiconductor device produced by integrating, for example, the following two types of transistors in their respective regions of a target substrate (hereinafter referred to as “carrier substrate”) commonly called a production substrate: (i) a polycrystalline silicon thin film transistor (non-monocrystalline silicon thin film transistor; non-monocrystalline silicon thin film device), and (ii) a MOS (metal oxide semiconductor) type monocrystalline silicon thin film transistor (monocrystalline silicon thin film device). The semiconductor device can further be integrated as, e.g., a driving circuit into an active matrix substrate including a display section.

The active matrix substrate includes: a target substrate; a silicon oxide film; a polycrystalline silicon thin film; a monocrystalline silicon thin film; a gate oxide film; a gate electrode; an interlayer insulating film; and a metal wire. The active matrix substrate further includes a TFT serving as a switching element. The active matrix substrate is used in, e.g., a liquid crystal display device.

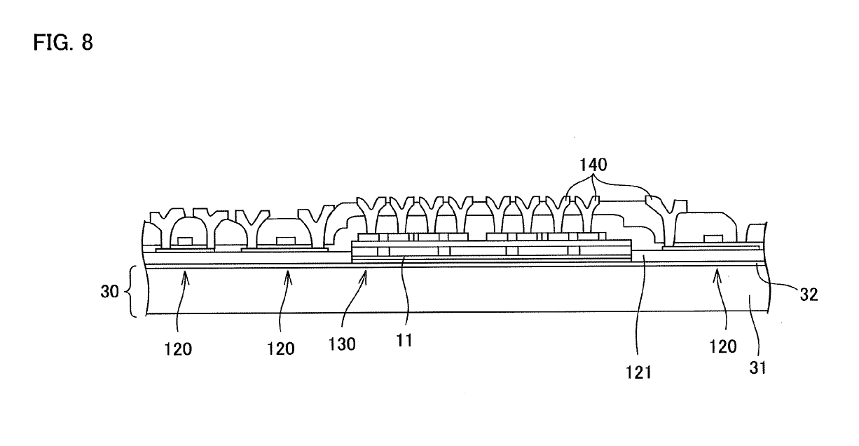

FIG. 8 illustrates an example of the semiconductor device produced in accordance with the present embodiment.

As illustrated in FIG. 8, the semiconductor device produced in accordance with the present embodiment includes on a carrier substrate 30: MOS-type polycrystalline silicon thin film transistors 120 each including a polycrystalline silicon thin film; MOS-type monocrystalline silicon thin film transistors 130 each including a monocrystalline silicon thin film; and metal wires 140.

The carrier substrate 30 includes: a light-transmitting target substrate (hereinafter referred to as “light-transmitting substrate”) 31; and an oxide film 32 formed substantially entirely over a surface of the light-transmitting substrate 31. The oxide film 32 is made of, e.g., SiO₂ (silicon oxide), and has a thickness of approximately 100 nm.

Each of the MOS-type polycrystalline silicon thin film transistors 120 is formed on an interlayer insulating film 121 formed on the oxide film 32. The polycrystalline silicon thin film is formed on the interlayer insulating film 121 in an isolated-shaped pattern, and has a thickness of approximately 200 nm.

Each of the MOS-type monocrystalline silicon thin film transistors 130 is formed in an isolated-shaped pattern in a region of the oxide film 32 which region is different from regions in which the polycrystalline silicon thin film transistors 120 are formed. The monocrystalline silicon thin film has a thickness of approximately 50 nm.

Any region in which the polycrystalline silicon thin film is formed and its adjacent region in which the monocrystalline silicon thin film is formed are separated from each other preferably by a distance of at least 0.3 μm, or more preferably by a distance of 0.5 μm or more.

Further, an interlayer insulating film is formed entirely over a surface of the carrier substrate 30 so as to cover the polycrystalline silicon thin film transistors 120 and the monocrystalline silicon thin film transistors 130. The interlayer insulating film has contact holes. The metal wires 140 via the contact holes are formed. The metal wires 140 are deposited from above onto the respective island-shaped regions of the polycrystalline silicon thin film and the monocrystalline silicon thin film.

It should be noted that according to the semiconductor device of the present embodiment, a blocking layer 11 for blocking substance diffusion is provided between the MOS-type monocrystalline silicon thin film transistors 130 and the oxide film 32, i.e., on an interface along which the MOS-type monocrystalline silicon thin film transistors 130 are bonded to the carrier substrate 30.

The method of the present embodiment for producing a semiconductor device is described below in sequential steps.

<Production of Device Substrate>

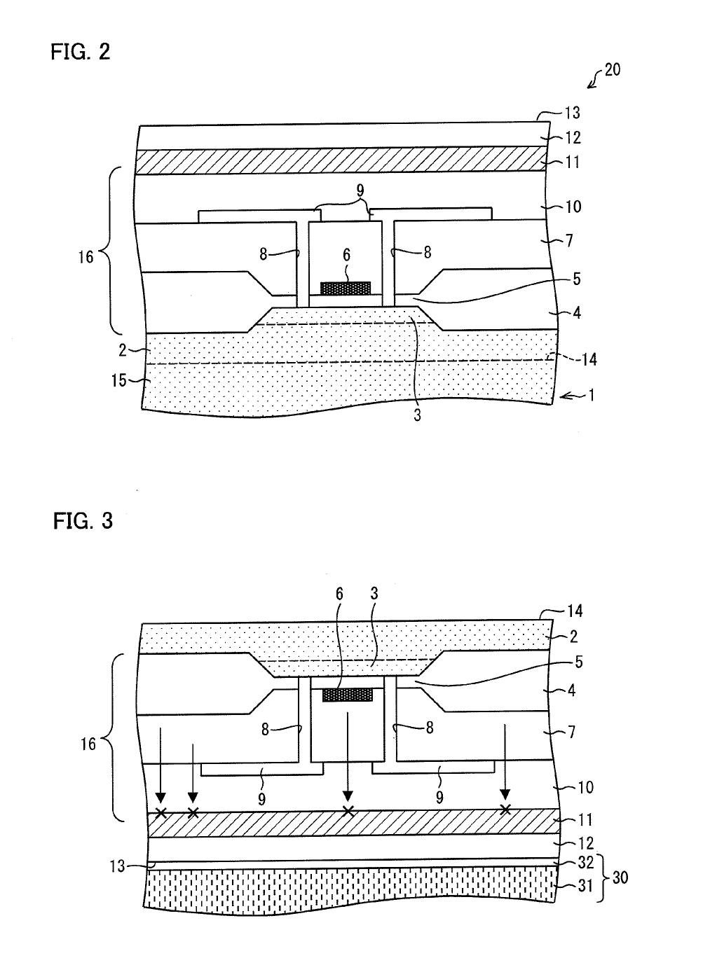

First, with reference to FIGS. 1 and 2, the following describes an example method for producing the semiconductor substrate to be bonded to the carrier substrate.

FIG. 2 is a cross-sectional view schematically illustrating an example structure of a main portion of the semiconductor substrate to be bonded to the carrier substrate.

The semiconductor substrate produced in the production example below is a device substrate (active silicon device) including: a wafer substrate formed with a silicon wafer; and a circuit which includes a monocrystalline silicon thin film and which is formed in accordance with a normal VLSI processing (e.g., CMOS, silicon) technique. The semiconductor substrate includes a silicon active layer as an active layer 3 illustrated in FIG. 2. The above circuit is formed in the active layer 3.

The production example below involves formation of, as the above circuit, a TFT (monocrystalline silicon thin film transistor; MOS-type monocrystalline silicon thin film transistor 130; see FIG. 8) which includes: a gate; a source/drain; and a channel region adjacent to the source/drain. The circuit formed on the active layer 3 may be (i) a TFT incorporated in a CMOS circuit or a VLSI, (ii) a CMOS circuit, or (iii) a VLSI.

The device substrate 20 illustrated in FIG. 2 is produced, for example, as described below. Among the steps below, the steps other than S105 and S106 shown in FIG. 1 are, although there may be some design variations according to need, identical to equivalent steps involved in conventional techniques. Thus, the production method, production conditions and the like for the other steps are not described in detail here. Those skilled in the art are, however, sufficiently capable of performing such other steps.

First, a surface of the wafer substrate 1 (monocrystalline silicon wafer) made of, e.g., monocrystalline silicon is thermally oxidized so that a SiO₂ (silicon dioxide) film is formed as an oxide film 2.

Next, a resist pattern is formed in a region other than a region in which the silicon-based circuit is to be formed. A dopant is then driven into the wafer substrate through the oxide film 2 so that a semiconductor region (well) is formed which is intended to serve as the active layer 3 (S101).

In the above step, doping, e.g., boron (B) ions as the dopant results in formation of a p well, whereas doping, e.g., phosphorus (P) ions or arsenic (As) ions results in formation of an n well.

Next, the oxide film 2 is thermally oxidized so that a thermal oxide film (field oxide film) is so formed as to surround the active layer 3. This thermal oxide film, i.e., a LOCOS (local oxidation of silicon) film 4, forms a device isolation region.

Then, a portion of the oxide film 2 which portion is present on the active layer 3 is grown by thermal oxidation so that a gate insulating film 5 is formed. A gate electrode 6 is then formed in a pattern on the gate insulating film 5. The gate electrode 6 is preferably made of polycrystalline silicon.

After that, a dopant is driven into the active layer 3, and activation annealing is then performed on the active layer so that the dopant (source/drain dopant) is activated. This forms a source region and a drain region.

In a case where As ions or P ions are driven into the p well to form a source region and a drain region, an n-type MOS (metal oxide semiconductor) transistor is formed as the silicon-based circuit. Meanwhile, in a case where fluorinated boron (BF₂) ions are driven into the n well to form a source region and a drain region, a p-type MOS transistor is formed as the silicon-based circuit.

Although FIG. 2 illustrates only a single MOS transistor, it is possible to simultaneously form an n-type MOS transistor and a p-type MOS transistor. This results in final formation of a CMOS transistor (S102).

After the above step, an interlayer insulating film 7 is formed of, e.g., NSG (non-doped silicate grass) or TEOS (tetraethoxysilane; Si(OC₂H₅)₄) on the above-formed circuit (silicon-based circuit). A surface of the interlayer insulating film 7 is planarized by CMP so that a cleavage separation layer (peel surface 14) to be formed by doping hydrogen ions (or rare gas ions) will be planar.

To reduce a thickness of the device substrate 20, in which the circuit is formed as above in the active layer 3, an unnecessary portion of the wafer substrate 1 (silicon) is removed from the rest of the device substrate by the following method: Ions to be used to cleave the wafer substrate 1 are doped into the wafer substrate 1. Then, for example, a heat treatment (annealing for peeling) is performed. This causes the wafer substrate 1 to be cleaved and peeled along the ion-doped portion (ion-doped surface) in the wafer substrate 1.

To following the above method, ions to be used to cleave the wafer substrate 1 are then doped from above the interlayer insulating film 7 so as to reach a portion along which the wafer substrate 1 is to be peeled. In the present production example, hydrogen ions, for example, are doped as the above ions. This forms a cleavage separation layer in the wafer substrate 1 (S103).

The cleavage separation layer in the wafer substrate 1 typically has a thickness within a range from 20 nm to 1,000 nm. The thickness of the cleavage separation layer, however, varies according to various factors such as a thickness of the wafer substrate 1, a quantity of the ions doped, a kind of the ions doped, and a period of the doping.

The hydrogen atoms have a peak concentration (Rp) at the portion along which the wafer substrate 1 illustrated in FIG. 2 is peeled, i.e., along the cleavage separation surface (peel surface 14). The cleavage separation surface is an interface between (i) a peel layer 15 to be peeled from the rest of the wafer substrate 1 and (ii) the transfer layer 16. The peak concentration of the hydrogen atoms along the peel surface 14 of the wafer substrate 1 falls within a range from 5×10¹⁵ atoms/cm² to 5×10¹⁷ atoms/cm².

The ions used to cleave the wafer substrate 1 are not limited to the hydrogen ions. As described above, rare gas ions may be used instead.

Further, the ion doping step (S103) may include, for example, a step of doping boron (B) ions so that the boron ions reach a depth identical to a depth at which the hydrogen ions are doped to be present. The additional doping of the boron ions allows the cleavage separation to occur at very low temperatures, generally within a range from 200° C. to 300° C. This greatly increases the number of options of the wafer substrate and the metals.

Further, other substances (ions) may additionally be used to improve performance of the cleavage separation. Such other substances are exemplified by at least one selected from the group consisting of rare gas ions (e.g., helium ions, neon ions, and argon ions) and silicon ions.

In this case, the cleavage separation layer (peel surface 14) contains a peak concentration of the additional element(s). An example of the additional element(s) is rare gas ions.

A temperature of the wafer substrate 1 is typically kept, through a period from the doping of the hydrogen ions in S103 to the subsequent S106, at a temperature lower than a temperature required for the cleavage separation (cleaving).

After S103, contact holes 8 are formed in the interlayer insulating film 7. Metal wiring is then provided so as to fill the contact holes 8. This forms, as first wiring layers 9, a source electrode and a drain electrode which are respectively connected to the source region and the drain region in the active layer 3 (S104).

The metal wiring is made of a material which has a high melting point and which is thus resistant to high-temperature treatments, i.e., the annealing for peeling and its subsequent recovery annealing.

Next, another oxide film made of, e.g., NSG or TEOS is deposited (stacked) over respective surfaces of the first wiring layers 9 as a planarizing layer 10 (bump compensation layer; interlayer insulating film). A surface of the oxide film is then planarized by CMP.

As a result of the above steps, the device substrate 20 is formed, in which a device to be transferred as the transfer layer 16 is formed on the wafer substrate 1.

After S104, a blocking layer 11 for blocking substance diffusion is formed on the planarizing layer 10. (S105).

The blocking layer 11 blocks, for example, substances that cause bubbles. Such substances are exemplified by an ion or molecule of at least one selected from the group consisting of water, hydrogen, and a hydrocarbon. Further, the atoms used to cleave the wafer substrate 1 and any substance derived from such atoms also possibly cause bubbles. In a case where any of these substances (each of which may be in the form of a molecule or an atom) is diffused to the bonding interface between the device substrate 20 and the carrier substrate due to such treatments as the heat treatment performed for the transfer of the transfer layer 16 and a heat treatment performed after the transfer, bubbles form at the bonding interface. This impairs device properties. The blocking layer 11 blocks diffusion of such bubble-causing substances.

The blocking layer 11 is made of, e.g., a material having an intracrystalline pore or intercrystalline gap which is smaller than the bubble-causing substances (each of which may be in the form of a molecule or an atom). Preventing transmission of such substances enables blocking of diffusion of the substances to the bonding interface.

A preferable example of the material of the blocking layer 11 is silicon nitride (SiNₓ). Silicon nitride has a close crystal structure, and thus prevents transmission of a dopant such as water, a hydrocarbon, and hydrogen. Hence, the blocking layer 11 made of silicon nitride effectively prevents the bubble-causing substances from being diffused to the bonding interface.

In addition to the above problem of the diffusion of the bubble-causing substances, performing a transfer by the transfer technique further involves the following problem: After the transfer layer is transferred onto the carrier substrate, mobile ions from the carrier substrate are diffused into the transfer layer. This decreases an operational capability (device performance) of the device. Mobile ions such as sodium ions in particular affect the operation of the device on the transfer layer side. The mobile ions can move as above not only during the production process, but also after the production due to, e.g., an environmental change.

To deal with this, in the state where the device substrate 20 is bonded to the carrier substrate (i.e., the transfer layer 16 is mounted on the carrier substrate), the blocking layer 11 is provided between (i) the bonding interface between the device substrate 20 and the carrier substrate and (ii) the transfer layer 16, i.e., between the carrier substrate and the transfer layer 16. The blocking layer is made of a material, such as silicon nitride, which has a close crystal structure that prevents transmission of a dopant. This allows the blocking layer 11 to block diffusion of the mobile ions. Thus, according to the above method, the mobile ions from the carrier substrate are prevented from being diffused into the transfer layer 16 after the transfer layer 16 is transferred onto the carrier substrate. This consequently prevents the device performance from being impaired due to the mobile ions.

The blocking layer 11 may be formed with, other than a silicon nitride film, a metal film having no columnar structure.

An example of the metal film having no columnar structure is a metal film formed by, e.g., deposition. Forming a metal film by deposition prevents such a metal film from having a columnar structure. Specific examples of the metal encompass tantalum, tungsten, and titanium.

The blocking layer 11 can be grown by a known deposition method such as plasma CVD (chemical vapor deposition).

The blocking layer 11 has a thickness preferably not smaller than 5 nm, or more preferably not smaller than 10 nm, in order to prevent nonuniformity in the thickness and quality. The thickness is preferably not larger than 200 nm, or more preferably not larger than 50 nm, in order to prevent an increase in a stress of the blocking layer.

After S105, an oxide film is formed on the blocking layer 11 as a bonding layer 12 (device-side bonding layer) (S106). The bonding layer forms a bonding surface 13, via which the device substrate 20 is bonded to the carrier substrate. An example of the oxide film is a silicon oxide (SiO₂) film.

In the case where the blocking layer 11 is made of silicon nitride, the blocking layer 11 has a surface which has an insufficient wettability (hydrophilicity) in its normal state. Thus, bonding the blocking layer 11 directly to the target substrate (light-transmitting substrate) is not preferable in terms of adhesion. In view of this, a silicon oxide film, for example, is provided as described above between the blocking layer 11 and the target substrate as the bonding layer 12. This improves the wettability of the device substrate 20 including the transfer layer, i.e., the wettability of the blocking layer 11. This in turn increases the adhesion between (i) the device substrate including the transfer layer 20 and (ii) the target substrate.

The oxide film is planarized by either CMP or SOG (spin on glass) so as to smooth the bonding surface. The oxide film thus planarized is located opposite from the oxide film which is included in the circuit formed on the active layer 3.

As described above, according to the present embodiment, the blocking layer 11 is formed on the device to be transferred (i.e., on the transfer layer 16), before the bonding layer 12 is formed. This allows the blocking layer 11 to be present between the device to be transferred and the bonding layer 12, i.e., between (i) the bonding interface between the device substrate 20 and the carrier substrate and (ii) the transfer layer 16.

According to the above arrangement, the blocking layer 11 is separated from the bonding interface between the device substrate 20 and the carrier substrate by a distance determined by a thickness of the bonding layer 12 (i.e., of the oxide film). Since the bonding layer 12 is present between the bonding interface and the blocking layer 11 in the state where the device substrate 20 is bonded to the carrier substrate, the bonding layer desirably has a thickness as small as possible, and is desirably planarized.

In a case where the blocking layer 11 has an irregular part, the bonding layer 12 formed between the bonding interface and the blocking layer 11 has a large volume as compared to a case where the blocking layer 11 is planar. A larger volume of the bonding layer 12 (SiO₂ film) results in a bubble-causing substance occurring in a larger amount and being more diffused. Hence, in the case where the blocking layer 11 has an irregular part, the bubble-causing substance tends to occur in a larger amount and to be more diffused. Thus, the bonding layer 12 preferably has a uniform thickness and, to achieve this, the blocking layer 11 preferably has a planar surface.

Further, the bubble-causing substance occurs and is diffused in the silicon oxide film as well. Hence, the silicon oxide film desirably has a small thickness. However, if the thickness is too small, it may be difficult to obtain a silicon oxide film having a uniform thickness and a uniform quality.

For these reasons, the thickness of the bonding layer 12, particularly in the case where the bonding layer 12 is a silicon oxide film, preferably falls within a range from 5 nm to 100 nm. Further, within this range, a smaller thickness is more preferable.

<Preparation of Carrier Substrate>

The carrier substrate (production substrate; target substrate; non-silicon substrate) of the present embodiment is, as described above, a target substrate formed with a light-transmitting substrate. An oxide film, e.g., a SiO₂ film, is formed substantially entirely over a surface of the light-transmitting substrate. The oxide film (SiO₂ film) has a thickness of approximately 100 nm.

The oxide film functions as a bonding layer on the carrier substrate side when the device substrate 20 is bonded to the carrier substrate. The target substrate, i.e., the light-transmitting substrate, may alternatively be used solely as the carrier substrate.

The light-transmitting substrate is made of a material such as glass, plastic, quartz, and metal foil. More specifically, examples of the material encompass glass having a high strain point. A preferable example is an alkali-free glass substrate which has a high strain point, and which is light-transmitting and amorphous.

The light-transmitting substrate is made of, for example, alkaline earth-aluminoborosilicate glass such as “1737 glass” manufactured by Corning Incorporated. Further, the light-transmitting substrate may be made of, for example, borosilicate glass, alkaline earth-zinc-lead-aluminoborosilicate glass, or alkaline earth-zinc-aluminoborosilicate glass.

As described above, the target substrate may, for example, be a glass substrate or a glass substrate provided with an insulating film on its surface (uppermost surface).

Alternatively, the light-transmitting substrate may be formed with one of various semiconductor films, or be made of a material sensitive to all (high-temperature) treatments for forming a monocrystalline activation circuit in S102.

<Transfer of Transfer Layer onto Carrier Substrate>

The semiconductor device of the present embodiment is, as described above, produced by the transfer technique, i.e., by transferring the transfer layer from the device substrate onto the carrier substrate.

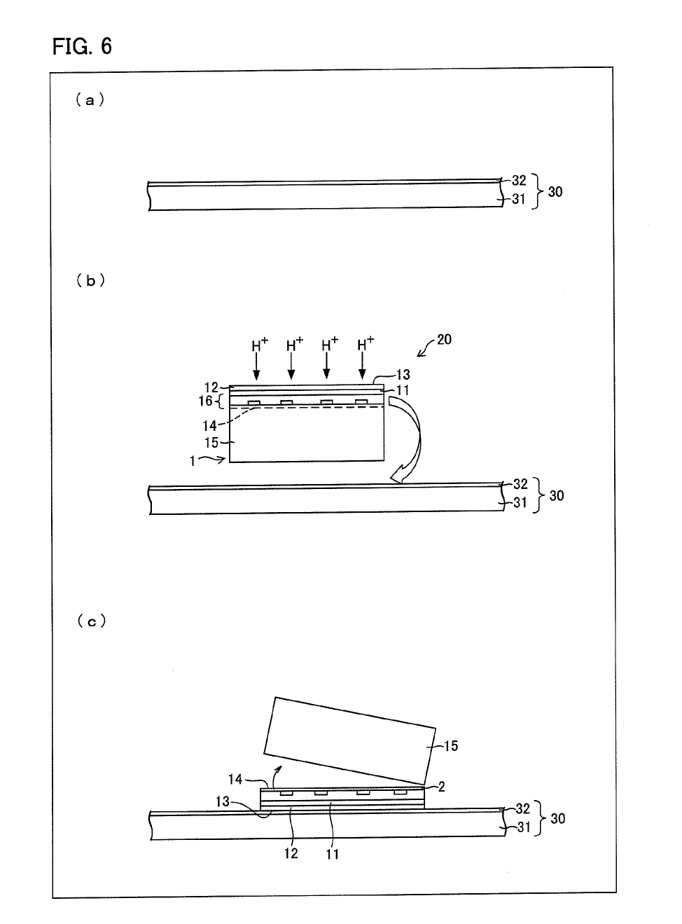

(a) through (c) of FIG. 6 illustrate steps through which the device substrate is attached to the carrier substrate, and the transfer layer is transferred from the device substrate onto the carrier substrate by the transfer technique involving the ion doping peeling method. The device substrate 20 in (a) through (c) of FIG. 6 is illustrated in a simplified manner.

First, as illustrated in (a) of FIG. 6, the oxide film 32 is formed on the light-transmitting substrate 31 as a bonding layer (bonding layer on the carrier substrate side), so that the carrier substrate 30 is prepared. An example of the oxide film is a SiO₂ film.

Next, as illustrated in (b) of FIG. 6, the device substrate 20 is bonded to the carrier substrate 30 (S107). The device substrate 20 includes monocrystalline silicon thin film transistors each of which is formed in advance as the circuit as described above.

As illustrated in (b) of FIG. 6, in the present step, the device substrate 20 may be bonded in the form of, e.g., a bonding wafer (chip; die) of a predetermined size by cutting (dicing) the device substrate into chips each having a predetermined size which matches a bonding region of the carrier substrate 30.

In S107, the device substrate 20 is spontaneously bonded to the carrier substrate 30 simply by causing the bonding layer 12 to contact the oxide film 32 and applying a small pressing force to the device substrate. The two substrates can be bonded to each other via no adhesive layer due to, e.g., contributions by Van der Waals force, electric dipolarity, and hydrogen bonding.

As a result, the blocking layer 11, which is provided between the device to be transferred and the bonding layer 12, is present between (i) the bonding interface, formed by the bonding surface 13, between the device substrate 20 and the carrier substrate 30 and (ii) the transfer layer 16.

As illustrated in (c) of FIG. 6, after the above step, the two substrates bonded to each other are, for example, heated (annealed for peeling) so that an unnecessary portion (of the wafer substrate 1; peel layer 15) of the device substrate 20 bonded to the carrier substrate 30 is cleaved along the peel surface 14 (S108).

FIG. 3 is a cross-sectional view schematically illustrating a structure of a main portion of the semiconductor device observed in a state where the peel layer 15 has been peeled (cleaved) after the device substrate 20 is bonded to the carrier substrate 30.

As described above, the cleavage of the wafer substrate 1 is induced by heat as an example. Specifically, as illustrated in (c) of FIG. 6, heat-treating the wafer substrate 1, in which hydrogen ions or the like have been doped, causes the wafer substrate 1 to be spontaneously cleaved and separated along the peel surface 14 (cleavage separation surface). More specifically, the hydrogen atoms doped in the form of the above hydrogen ions are present at the highest concentration at a position (Rp position), where many lattice defects occur. Since a large number of hydrogen atoms are present along the peel surface 14 (cleavage separation layer), heat-treating the wafer substrate 1 causes platelet-shaped microbubbles to form along the peel surface. A pressure caused by such formation causes the wafer substrate 1 to be cleaved and separated along the peel surface 14 (Rp position), on which the hydrogen atoms have its peak concentration.

The wafer substrate 1 is cleaved by, for example, raising a temperature of the cleavage separation layer, i.e., a temperature of the hydrogen ion-doped portion, to a temperature not lower than a temperature at which the hydrogen atoms are desorbed from the wafer substrate 1 (specifically, silicon). In the present production example, the two substrates (bonded pair) are heated to, for example, 600° C.

As described above, the cleavage separation layer (in particular, the peel layer 14) of the wafer substrate 1 contains a large number of atoms (e.g., hydrogen atoms or rare gas atoms) which cause microbubbles to form along the cleavage separation layer and which are thus used to cleave the wafer substrate 1. In addition, both the interlayer insulating film 7 and the planarizing layer 10 contain large amounts of substances (bubble-causing substances), such as water and a hydrocarbon, which cause bubbles.

The above bubble-causing substances tend to be diffused, e.g., during the transfer of the transfer layer 16 and/or during the heat treatment performed after the transfer.

In view of this, the method of the present embodiment for producing the semiconductor device provides the blocking layer 11, as described above, between (i) the bonding interface (bonding surface 13) between the device substrate 20 and the carrier substrate 30 and (ii) the device to be transferred (i.e., the transfer layer 16). As illustrated in FIG. 3, this prevents the bubble-causing substances from being diffused to the bonding interface. Hence, the above method prevents bubbles from forming at the bonding interface.

Further, as described above, the blocking layer 11 is provided between the bonding interface and the transfer layer 16, i.e., between the carrier substrate 30 and the transfer layer 16. The blocking layer is made of a material, such as silicon nitride, which has a close crystal structure that prevents transmission of a dopant. The blocking layer 11 can thus block diffusion of mobile ions. According to the above method, mobile ions from the carrier substrate are hence prevented from being diffused into the transfer layer 16 after the transfer layer 16 is transferred onto the carrier substrate. As a result, it is possible to prevent the device performance from being impaired due to such mobile ions.

After the peel layer 15 has been peeled, unnecessary silicon may remain on a surface of the device substrate 20.

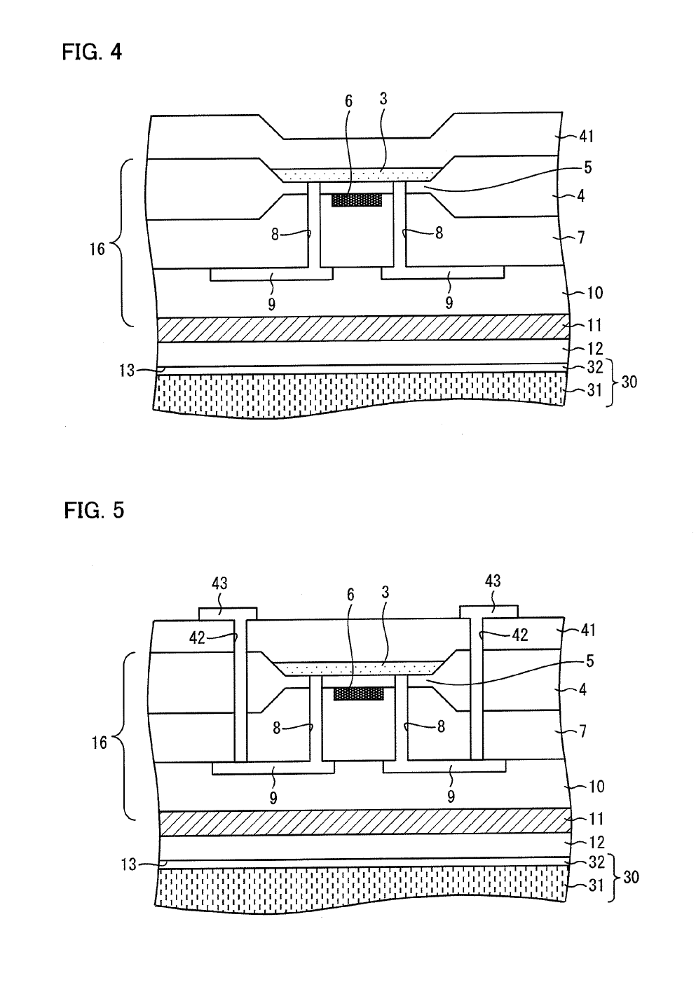

Thus, if necessary, as illustrated in FIG. 4, such unnecessary silicon remaining after the cleaving is then removed (for thickness reduction) (S109), and an oxide film, for example, is formed as a protection insulating film 41 on the transfer layer 16, from which the above unnecessary silicon has been removed (S110).

The unnecessary silicon may be removed by a normal process such as reactive ion etching and dry etching.

FIG. 4 is a cross-sectional view schematically illustrating an arrangement of the semiconductor device observed in a state where, after the peel layer 15 has been peeled, a thickness of the active layer 3 is reduced and the protection insulating film 41 is then formed.

The oxide film used as the protection insulating film 41 may also be used as a base coat material for later polysilicon processing for a hybrid circuit.

Next, as illustrated in FIG. 5, contact holes 42 are formed through the protection insulating film 41, the LOCOS film 4, and the interlayer insulating film 7 so that second wiring layers 43 are so formed as the metal wires 140 as to be connected to the their corresponding first wiring layers 9 through the contact holes 42.

FIG. 5 is a cross-sectional view schematically illustrating an arrangement of the semiconductor device observed in a state where the second wiring layers 43 are formed. The second wiring layers 43 are further connected to wiring layers (not shown) in the carrier substrate 30.

After the above steps, polycrystalline silicon thin film transistors are formed on the carrier substrate 30 by a well-known normal process of forming a polycrystalline silicon thin film transistor. As a result, a polycrystalline silicon thin film transistor and a monocrystalline silicon thin film transistor can be integrated, as described above, in their respective regions of the carrier substrate 30.

In the above production example, the wafer substrate 1 is cleaved by a heat treatment. However, the cleaving method of the present embodiment is not limited to this. In a case where, for example, the substrates are bonded to each other by a strength greater than a strength required for the cleavage separation, the cleavage separation may be performed by a mechanical method (mechanical processing). A specific example of the “mechanical processing” is a processing in which the bonded substrates are firmly fixed and a shear stress is applied to the substrates in parallel with the peel surface 14.

The mechanical cleavage separation processing may additionally include an annealing step.

To facilitate the cleavage separation, the cleavage separation layer may, for example, be formed with a porous silicon layer.

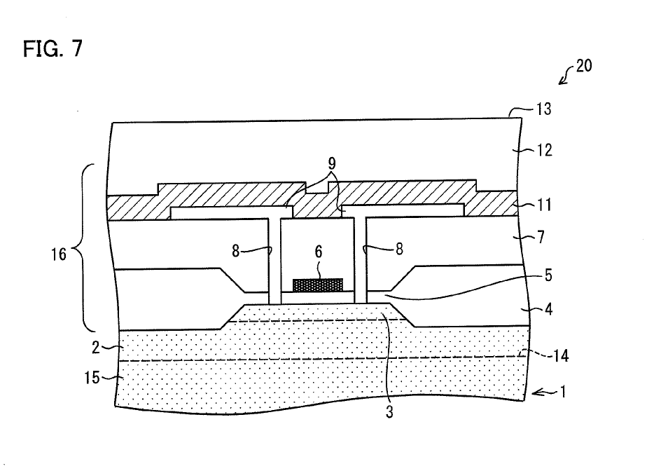

As illustrated in FIG. 2, the above production example describes the case in which the blocking layer 11 is provided above the first wiring layers 9 via the planarizing layer 10. Alternatively, as illustrated in FIG. 7, the blocking layer 11 may be provided directly on the first wiring layers 9. However, since the blocking layer 11 is preferably planar for the reason described above, the blocking layer 11 is preferably provided on the planarizing layer 10 as illustrated in FIG. 2.

The above production example describes the case in which a silicon-based circuit is formed in the transfer layer in advance. However, the present embodiment can be effective also in a case where the transfer layer 16 is a single monocrystalline silicon film. This case may be realized by, for example: forming the blocking layer 11 on a monocrystalline silicon film; forming an oxide film as a bonding layer 12, via which the monocrystalline silicon film is to be bonded to the carrier substrate 30; and bonding the monocrystalline silicon film to the carrier substrate 30 via the bonding layer 12 and the blocking layer 11.

In the above production example, the active layer 3 is made of monocrystalline silicon (a-Si). However, the active layer 3 may be made of either monocrystalline silicon or polycrystalline silicon (p-Si).

The above production example describes the case in which thin film transistors are formed on the carrier substrate 30 after the transfer layer 16 is transferred onto the carrier substrate 30. Naturally, thin film transistors may be formed on the carrier substrate 30 before the transfer layer 16 is transferred onto the carrier substrate 30. In other words, the target substrate used in the present embodiment may be provided with thin film transistors formed thereon. The case in which thin film transistors are formed in advance may be realized by removing by etching only a portion of the interlayer insulating film which is included in each thin film transistor, the portion corresponding to a bonding region, so that a portion of the glass substrate is exposed as a bonding interface. Alternatively, as in the device substrate used in the above production example, a blocking layer and a silicon oxide film may be so formed on the interlayer insulating film included in each thin film transistor as to serve as a bonding interface. Further alternatively, the interlayer insulating film included in each thin film transistor may itself be used to form a bonding interface.

As described above, the semiconductor device of the present embodiment is a semiconductor device produced by (i) doping hydrogen ions or ions of a rare gas into a semiconductor substrate in which a transfer layer is formed, then (ii) bonding the semiconductor substrate to a target substrate, and (iii) transferring the transfer layer onto the target substrate by cleaving the semiconductor substrate at a portion in which the hydrogen ions or the rare gas ions are doped, the semiconductor device comprising: a blocking layer for blocking substance diffusion, the blocking layer being provided between (i) a bonding interface between the semiconductor substrate and the target substrate and (ii) the transfer layer.

As described above, the method of the present embodiment for producing a semiconductor device is a method for producing a semiconductor device produced by (i) doping hydrogen ions or ions of a rare gas into a semiconductor substrate in which a transfer layer is formed, then (ii) bonding the semiconductor substrate to a target substrate, and (iii) transferring the transfer layer onto the target substrate by cleaving the semiconductor substrate at a portion in which the hydrogen ions or the rare gas ions are doped, the method comprising: providing a blocking layer for blocking substance diffusion between (i) a bonding interface between the semiconductor substrate and the target substrate and (ii) the transfer layer.

According to each of the above arrangements, for example, the bubble-causing substance from the transfer layer can be prevented from being diffused across the bonding interface between the semiconductor substrate and the target substrate. Hence, it is possible to prevent bubbles from forming at the bonding interface.

According to each of the above arrangements, the blocking layer is provided between the bonding interface and the transfer layer, i.e., between the target substrate and the transfer layer. This allows the blocking layer to block diffusion of the mobile ions. Thus, according to each of the above arrangements, the mobile ions from the target substrate are prevented from being diffused into the transfer layer after the transfer layer is transferred onto the target substrate. This consequently prevents the device performance from being impaired due to the mobile ions.

The blocking layer may preferably block diffusion of a mobile ion from the target substrate.

As described above, the blocking layer is provided between the bonding interface and the transfer layer, i.e., between the target substrate and the transfer layer. This allows the blocking layer to block diffusion of the mobile ions. Thus, according to the above arrangement and method, the mobile ions from the target substrate are prevented from being diffused into the transfer layer after the transfer layer is transferred onto the target substrate. This consequently prevents the device performance from being impaired due to the mobile ions.

The blocking layer may preferably be made of silicon nitride. Silicon nitride has a close crystal structure, and thus prevents transmission of a dopant such as water, a hydrocarbon, and hydrogen. Hence, the blocking layer made of silicon nitride effectively prevents a bubble-causing substance from being diffused to the bonding interface.

In addition to the above problem, performing a transfer by the transfer technique further involves the following problem: After the transfer layer is transferred onto the target substrate, mobile ions from the target substrate are diffused into the transfer layer. This decreases an operational capability (device performance) of the device. Mobile ions such as sodium ions, in particular, affect the operation of the device on the transfer layer side.

As described above, the blocking layer, which has a close crystal structure that prevents transmission of a dopant, is provided between the bonding interface and the transfer layer, i.e., between the target substrate and the transfer layer. This allows the blocking layer to block diffusion of the mobile ions. Thus, according to the above arrangement, the mobile ions from the target substrate are prevented from being diffused into the transfer layer after the transfer layer is transferred onto the target substrate. This consequently prevents the device performance from being impaired due to the mobile ions.

A silicon oxide film having a uniform thickness may preferably be provided between the blocking layer and the target substrate.

The blocking layer may, depending on its kind, have a surface which has an insufficient wettability (hydrophilic) in the case where, for example, the blocking layer is made of silicon nitride, a metal or the like. Thus, bonding the blocking layer directly to the target substrate is not preferable in terms of adhesion. In view of this, the silicon oxide film is provided between the blocking layer and the target substrate. This improves the wettability of the surface of the blocking layer (e.g., the silicon nitride film), and thus increases the adhesion between the transfer layer and the target substrate. Further, in the case where the blocking layer (e.g., the silicon nitride film) has an irregular part, the silicon oxide film formed between the blocking layer and the bonding interface of the target substrate has a large volume as compared to the case where the blocking layer is planar. A larger volume of the silicon oxide film results in a bubble-causing substance occurring in a larger amount and being more diffused. Hence, in the case where the blocking layer has an irregular part, the bubble-causing substance tends to occur in a larger amount and to be more diffused. Thus, the silicon oxide film preferably has a uniform thickness.

In this case, the thickness of the silicon oxide film may preferably fall within a range from 5 nm to 100 nm.

The distance between the blocking layer and the target substrate is determined by the thickness of the silicon oxide film. Further, the substance that causes bubbles occurs and is diffused in the silicon oxide film as well. Thus, the silicon oxide film desirably has a thickness as small as possible. However, if the thickness is too small, it may be difficult to obtain a silicon oxide film having a uniform thickness and a uniform quality. Thus, the silicon oxide film desirably has a thickness which falls within the above range.

The present invention is not limited to the description of the embodiments above, but may be altered in various ways by a skilled person within the scope of the claims. Any embodiment based on a proper combination of technical means disclosed in different embodiments is also encompassed in the technical scope of the present invention.

### INDUSTRIAL APPLICABILITY

The method of the present invention for producing a semiconductor substrate prevents device properties from being impaired due to bubbles which are caused by diffusion of a bubble-causing substance and which form at the bonding interface between the semiconductor substrate and the target substrate.

1. A semiconductor device produced by (i) doping hydrogen ions or icons of a rare gas into a semiconductor substrate in which a transfer layer is formed, then (ii) bonding the semiconductor substrate to a target substrate, and (iii) transferring the transfer layer onto the target substrate by cleaving the semiconductor substrate at a portion in which the hydrogen ions or the rare gas ions are doped,
the semiconductor device comprising:
a blocking layer for blocking substance diffusion,
the blocking layer being provided between (i) a bonding interface between the semiconductor substrate and the target substrate and (ii) the transfer layer.

2. The semiconductor device according to claim 1, wherein the blocking layer blocks diffusion of a substance from the transfer layer which substance causes a bubble.

3. The semiconductor device according to claim 2, wherein the blocking layer is made of a material having an intracrystalline pore or intercrystalline gap smaller than the substance which causes the bubble.

4. The semiconductor device according to claim 2, wherein the substance which causes the bubble is ions or molecules of at least one selected from the group consisting of water, hydrogen, and a hydrocarbon.

5. The semiconductor device according to claim 1, wherein the blocking layer is made of silicon nitride.

6. The semiconductor device according to claim 1, further comprising:
a silicon oxide film having a uniform thickness and provided between the blocking layer and the target substrate.

7. The semiconductor device according to claim 6, wherein the thickness of the silicon oxide film falls within a range from 5 nm to 100 nm.

8. The semiconductor device according to claim 1, wherein the blocking layer blocks diffusion of a mobile ion from the target substrate.

9. A method for producing a semiconductor device produced by (i) doping hydrogen ions or ions of a rare gas into a semiconductor substrate in which a transfer layer is formed, then (ii) bonding the semiconductor substrate to a target substrate, and (iii) transferring the transfer layer onto the target substrate by cleaving the semiconductor substrate at a portion in which the hydrogen ions or the rare gas ions are doped,
the method comprising:
providing a blocking layer for blocking substance diffusion between (i) a bonding interface between the semiconductor substrate and the target substrate and (ii) the transfer layer.
